(19) United States
(12) Patent Application Publication
(10) Pub. No.: US 2011/0227595 A1
(43) Pub. Date: Sep. 22, 2011

(54) INTERFACE MEMBER, TEST SECTION UNIT AND ELECTRONIC DEVICE HANDLING APPARATUS

(75) Inventor: Satoshi Takeshita, Tokyo (JP)

(73) Assignee: ADVANTEST CORPORATION, Tokyo (JP)

(21) Appl. No.: 13/122,112

(22) PCT Filed: Oct. 9, 2008
(86) PCT No.: PCT/JP2008/068344

§ 371 Date: Jun. 8, 2011

(51) Int. Cl. G01R 31/00

(52) U.S. Cl. 324/756.02

(57) ABSTRACT

An interface member 52, being provided between a body part of a test head 5 to be used in an electronic device testing apparatus 10 and a socket board 51 having a socket 512 to be mounted with an electronic device 2 to be tested and a plurality of socket side connectors 514 electrically connected to the socket 512, for electrically connecting the body part of the test head 5 with the socket board 51: comprising IF side connectors 524 to be engaged with the socket side connectors 514, an upper frame 521 for supporting the IF side connector 524 and a frame-shaped lower frame 522 provided under the upper frame 521; wherein the upper frame 521 has a hole 521h formed thereon for allowing a plurality of IF side connectors 524 to pass through, a heat insulator 525 is provided between a plurality of IF side connectors 524 passing through the hole 521h, and inside the frame-shaped lower frame 522 is filled with a plurality of block-shaped heat insulators 526, wherein cables 524c of the IF side connectors 524 pass through.

### TECHNICAL FIELD

The present invention relates to an interface member for electrically connecting a body part of a test head with a socket board in an electronic device testing apparatus, a test section unit provided with the interface member and socket board and detachably attached to a body part of a test head, a test head, and an electronic device testing apparatus.

### BACKGROUND ART

In a production procedure of an electronic device, such as an IC device, an electronic device testing apparatus is necessary for testing the finally produced electronic device. A device for conducting a test by giving a thermal stress of a high temperature and a low temperature to an IC device has been known as a kind of testing apparatuses as such.

In the above testing apparatus, a test chamber is formed at an upper portion of a test head. While controlling a temperature in the test chamber to a predetermined set temperature by an air, a test tray holding a plurality of IC devices which have been brought to a predetermined set temperature in the same way is conveyed to sockets on the test head, where a test is conducted by pressing the IC devices against the sockets to connect thereto. IC devices are tested under a thermal stress as such and classified at least to good ones and defective ones.

The test head is generally provided with a test head body accommodating a signal module for processing signals and a test section unit (referred to as a Hi-Fix or mother board in some cases) attached detachably to the test head body. The test section unit is provided with a socket board having the socket and an interface member (also referred to as a performance board or a mother board in some cases) provided between the socket board and the test head body and connecting the two electrically.

FIG. 9 is a sectional view showing an internal configuration of a conventional test section unit 50. As shown in FIG. 9, the upper portion of the test section unit 50 positions inside a test chamber 102. A socket board 51 provided to the test section unit 50 comprises a socket 512 to be mounted with an IC device 2 and a plurality of socket side connectors 514 connected electrically to the socket 512.

On the other hand, the interface member 52 has a hollow upper frame 521, a frame-shaped lower frame 522, and a plurality of interface member side connectors (hereinafter, referred to as “IF side connectors”) provided to a hole 521h on a substrate portion of the upper frame 521. Cables 524c electrically connected to the test head body extend from the IF side connectors 524. The IF side connectors 524 engage with the socket side connectors 514.

In the configuration of the above conventional test section unit 50, since the holes 521h on the upper frame 521 open between a plurality of the IC side connectors 524, an internal space 510 of the socket board 51, an internal space 520a of the upper frame 521 and an internal space 520b of the lower frame 522 are continuous. Also, the internal space 520a of the upper frame 521 and the internal space 520b of the lower frame 522 are not specially sealed and open to the outside of the apparatus and an internal space of the test head body.

In the above configuration, airtightness of the internal spaces 510, 520a and 520b of the test section unit 50 is low and the thermal insulation property is insufficient, so that a heat of the test chamber 102 is liable to be lost from the test section unit 50. Also, even if a temperature-adjusted air is introduced to the internal spaces 510, 520a and 520b of the test section unit 50, due to a relatively large volume of the internal spaces 510, 520a and 520b, convection arises in the internal spaces 510, 520a and 520b and the heat is released to the outside. Furthermore, even if a dry air is introduced to the internal spaces 510, 520a and 520b of the test section unit 50 to prevent dew condensation during a low temperature test, the dry air escapes to the outside and dew condensation cannot be prevented effectively.

When a heat of the test chamber 102 or a heat of a temperature-adjusted air is lost as explained above, it becomes difficult to control IC devices 2 to be a predetermined set temperature and a test at a precise temperature becomes impossible. Also, when dew condensation arises inside the test section unit 50, short-circuiting possibly occurs in connectors, etc.

### DISCLOSURE OF THE INVENTION

The present invention was made in consideration of the above circumstances and has as an object thereof to provide an interface member having a configuration with high airtightness and a superior thermal insulating property, a test section unit, a test head and an electronic device testing apparatus.

To attain the above object, first, the present invention provides an interface member, being provided between a body portion of a test head to be used in an electronic device testing apparatus and a socket board having a socket to be mounted with an electronic device to be tested and a plurality of connectors electrically connected to the socket, for electrically connecting the body portion of the test head with the socket board, comprising: connectors to be engaged with socket side connectors provided to the socket board, and a frame for supporting the connectors; wherein the frame has a hole formed thereon for allowing a plurality of the connectors to pass through, and a heat insulator is provided between the plurality of connectors passing through the same hole (Invention 1).

Second, the present invention provides an interface member, being provided between a body portion of a test head to be used in an electronic device testing apparatus and a socket board having a socket to be mounted with an electronic device to be tested and a plurality of connectors electrically connected to the socket, for electrically connecting the body portion of the test head with the socket board, comprising: connectors to be engaged with socket side connectors provided to the socket board, and a frame for supporting the connectors; wherein a heat insulator is provided between a cable extending from one of the connectors and a cable extending from another one of the connectors (Invention 2).

In the invention above (Invention 2), preferably, the heat insulator has a hole formed thereon, and the cable passes through the hole of the heat insulator (Invention 3).

In the invention above (Invention 2), preferably, the heat insulator fills the frame in the plane direction (Invention 4).

In the invention above (Invention 4), preferably, the heat insulator has a block shape, and a plurality of the block-shaped heat insulators are provided contiguously to fill the frame in the plane direction (Invention 5).

In the invention above (Invention 2), preferably, the heat insulator is made of an elastic material (Invention 6).

In the invention above (Invention 6), preferably, the elastic material is a porous elastic material having a number of closed cells (Invention 7).

In the invention above (Invention 2), preferably, the frame has a hole formed thereon for allowing a plurality of the connectors to pass through; and a second heat insulator is provided between the plurality of connectors passing through the hole (Invention 8).

In the invention above (Invention 2), preferably, inside of the frame form a nearly airtight space (Invention 9).

In the invention above (Invention 9), preferably, a dry air is introduced to an internal space of the frame (Invention 10).

In the invention above (Invention 10), the heat insulator has a vent path formed thereon for introducing the dry air (Invention 11).

Third, the present invention provides an interface member, being provided between a body portion of a test head to be used in an electronic device testing apparatus and a socket board having a socket to be mounted with an electronic device to be tested and a plurality of connectors electrically connected to the socket, for electrically connecting the body portion of the test head with the socket board, comprising: connectors to be engaged with socket side connectors provided to the socket board, and a frame for supporting the connectors; wherein a heat insulating sheet spread in the plane direction of the frame is provided between a plurality of the connectors (Invention 12).

In the invention above (Invention 12), preferably, the connector has a flange formed beneath an engaging portion; the heat insulating sheet has a hole formed thereon having a size for allowing the engaging portion of the connector to pass through but not allowing the flange to pass through; and the heat insulating sheet let the engaging portion of the connector pass through the hole and contact closely with the flange (Invention 13).

Fourth, the present invention provides a test section unit to be attached to a body portion of a test head, comprising: a socket board having a socket to be mounted with an electronic device to be tested and a plurality of connectors electrically connected to the socket, and the interface member as set forth in claim 1; wherein a space surrounded by the socket board and the interface member is nearly airtight (Invention 14).

Fifth, the present invention provides a test section unit to be attached to a body portion of a test head, comprising: a socket board having a socket to be mounted with an electronic device to be tested and a plurality of connectors electrically connected to the socket, and the interface member as set forth in claim 2 (Invention 15).

Sixth, the present invention provides a test section unit to be attached to a body portion of a test head, comprising: a socket board having a socket to be mounted with an electronic device to be tested and a plurality of connectors electrically connected to the socket, and the interface member as set forth in claim 8; wherein a space surrounded by the socket board and the interface member is nearly airtight (Invention 16).

Seventh, the present invention provides a test section unit to be attached to a body portion of a test head, comprising: a socket board having a socket to be mounted with an electronic device to be tested and a plurality of connectors electrically connected to the socket, and the interface member as set forth in claim 12; wherein a space surrounded by the socket board and the interface member is nearly airtight (Invention 17).

In the invention above (Inventions 14, 16 and 17), preferably a dry air is introduced to the nearly airtight space (Invention 18).

In the invention above (Invention 18), preferably, the interface member has a vent hole formed thereon for introducing the dry air (Invention 19).

Eighth, the present invention provides a test head, comprising: a test head body; and the test section unit as set forth in any one of claims 14 to 17 to be attached to the test head body (Invention 20).

Ninth, the present invention provides a test head, comprising: a test head body; the test section unit as set forth in any one of claims 14, 16 and 17 to be attached to the test head body; and a device for supplying a dry air to the nearly airtight space in the test section unit (Invention 21).

Tenth, the present invention provides a test head comprising a test head body, a test section unit to be attached to the test head body and provided with the interface member as set forth in claim 10, and a device for supplying a dry air to inside the frame in the interface member (Invention 22).

Eleventh, the present invention provides an electronic device testing apparatus, comprising: the test head as set forth in claim 20; and an electronic device handling apparatus for handling an electronic device to be tested and mounting the electronic device on be tested to a socket of the test head (Invention 23).

Twelfth, the present invention provides an electronic device testing apparatus, comprising: the test head as set forth in claim 21; and an electronic device handling apparatus for handling an electronic device to be tested and mounting the electronic device to be tested on a socket of the test head (Invention 24).

Thirteenth, the present invention provides an electronic device testing apparatus, comprising: the test head as set forth in claim 22; and an electronic device handling apparatus for handling an electronic device to be tested and mounting the electronic device to be tested on a socket of the test head (Invention 25).

In the invention above (Inventions 23 to 25), preferably, the electronic device handling apparatus is provided with a chamber for heating and/or cooling an electronic device to be tested to be a predetermined temperature (Invention 26).

The interface member or test section unit according to the present invention has high airtightness in internal spaces thereof and an excellent heat insulating property. Accordingly, more precise temperature control of electronic devices becomes possible, and dew condensation in the interface member or the test section unit can be prevented effectively due to an introduction of a dry air.

### BRIEF DESCRIPTION OF DRAWINGS

FIG. 1 is an overall view from the side of an IC device testing apparatus according to an embodiment of the present invention.

FIG. 2 is a perspective view of a handler in the same embodiment.

FIG. 3 is a sectional view of a key part inside a test chamber of the handler in the same embodiment.

FIG. 4 is a sectional view of a test section unit in the same embodiment.

FIG. 5 is a perspective view of an upper frame of an interface member in the same embodiment.

FIG. 6 is a perspective view of a lower frame of the interface member in the same embodiment.

FIG. 7 is a sectional view of a test section unit in another embodiment.

FIG. 8 is a perspective view of an interface member side connector in the same embodiment.

FIG. 9 is a sectional view of a conventional test section unit.

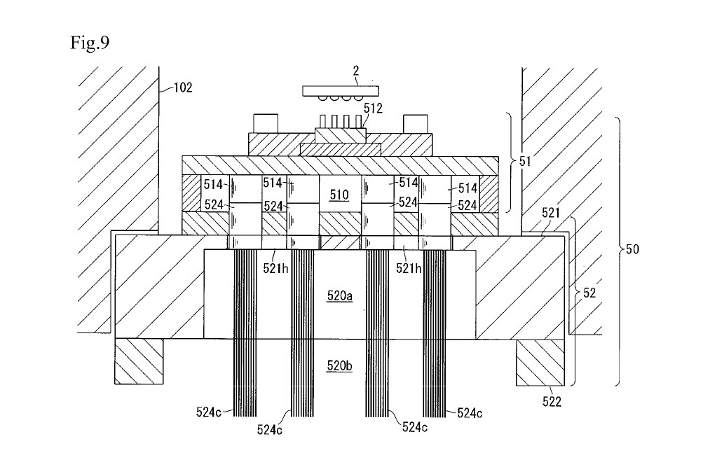

### EXPLANATION OF REFERENCE NUMBERS

1 . . . handler (electronic device handling apparatus)
2 . . . IC device (electronic device)
10 . . . IC device (electronic device) testing apparatus
5 . . . test head
50 . . . test section unit
   51 . . . socket board
      510 . . . internal space
      512 . . . socket
   514 . . . socket side connector
   52 . . . interface member
      520 . . . internal space
      521 . . . upper frame
      521h . . . hole
      522 . . . lower frame
      524 . . . interface member side connector
         524a . . . engaging portion
         524b . . . flange
         524c . . . cable
      525, 525a, 525b and 526 . . . heat insulator
      526h . . . hole
      528 and 529 . . . dry air vent path
   53 . . . heat insulating sheet

### BEST MODE FOR CARRYING OUT THE INVENTION

Below, an embodiment of the present invention will be explained based on the drawings.

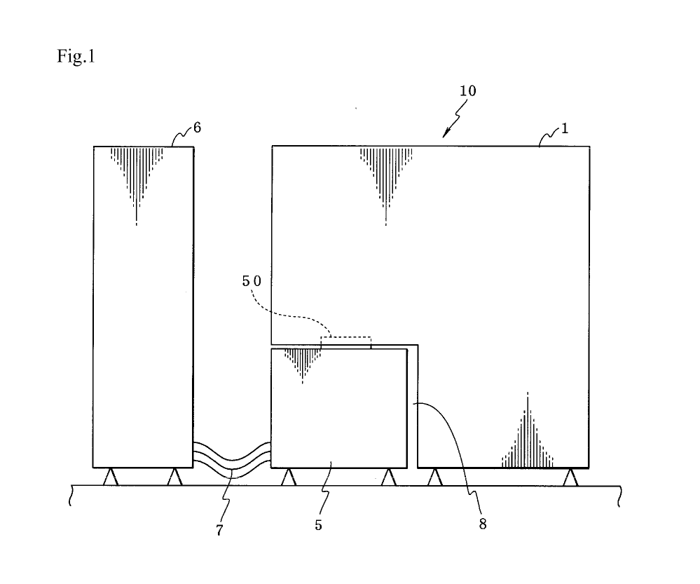

First, the overall configuration of an IC device testing apparatus provided with a handler according to an embodiment of the present invention will be explained. As shown in FIG. 1, the IC device testing apparatus 10 comprises a handler 1, a test head 5 and a main testing device 6. The handler 1 performs operations of successively conveying IC devices (an example of electronic devices) to be tested to sockets provided to the test head 5, classifying IC devices finished with the test based on the test results and storing on predetermined trays.

The sockets provided to the test head 5 are electrically connected to the main testing device 6 via a cable 7. IC devices detachably mounted on the sockets are connected to the main testing apparatus 6 via the cable 7, and a test is conducted on the IC devices by test electric signals from the main testing device 6.

At a lower portion of the handler 1, a control device for mainly controlling the handler 1 is incorporated while partially leaving a space 8. The test head 5 is placed in the space 8 in a replaceable way, and IC devices can be mounted on the sockets on the test head 5 via through holes formed on the handler 1.

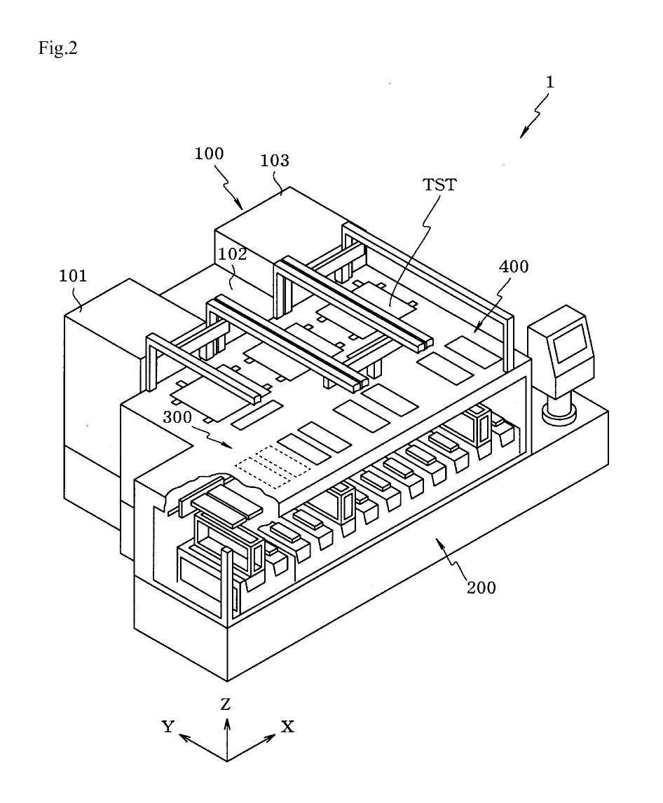

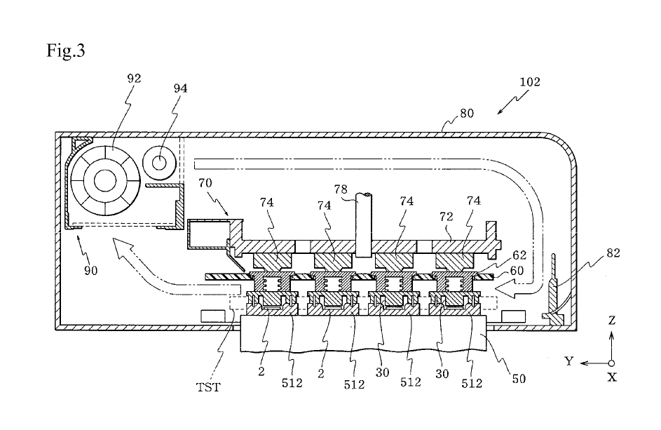

The handler 1 is a device for testing IC devices as electronic devices to be tested under a higher temperature condition (high temperature) or a lower temperature condition (low temperature) than the normal temperature. The handler 1 comprises, as shown in FIG. 2, a chamber 100 composed of a constant temperature chamber 101, a test chamber 102 and an unsoak chamber 103. The upper portion of the test head 5 is inserted to inside of the test chamber 102 as shown in FIG. 3, where a test is conducted on IC devices 2.

As shown in FIG. 2, the handler 1 of the present embodiment comprises an IC magazine 200 for storing pre-test IC devices and storing classified post-test IC devices, a loader section 300 for transferring IC devices to be tested sent from the IC magazine 200 to the chamber section 100, a chamber section 100 including the test head, and an unloader section 400 for taking out and classifying IC devices tested in the chamber section 100.

A large number of the IC devices are held on a customer tray before being set in the handler 1 and supplied in that state to the IC magazine 200 of the handler 1 shown in FIG. 2. In the loader section 300, the IC devices 2 are reloaded from the customer tray to a test tray TST to be conveyed in the handler 1. Inside the handler 1, the IC devices are moved in a state of being loaded on the test tray TST, given a thermal stress of a high temperature or a low temperature in the chamber 100, tested whether or not they operate appropriately, and classified in the unloader section 400 in accordance with the test results.

As shown in FIG. 2, the chamber 100 comprises the constant temperature chamber 101 for giving a thermal stress of a desired high or low temperature to IC devices to be tested loaded on the test tray TST, a test chamber 102 wherein IC devices in a state of having been given a thermal stress in the constant temperature chamber 101 are mounted on the sockets on the test head, and the unsoak chamber 103 for removing the given thermal stress from the IC devices tested in the test chamber 102.

In the unsoak chamber 103, IC devices are brought back to the room temperature by ventilation when a high temperature was applied in the constant temperature chamber 101, and brought back to a temperature of a degree not causing dew condensation by heating with a hot air or a heater, etc. when a low temperature was applied in the constant temperature chamber 101. Then, the IC devices brought back to the normal temperature are taken out to the unloader section 400.

A vertical conveyor is provided to the constant temperature chamber 101, and a plurality of test trays supported by the vertical conveyor wait for the test chamber 102 to become vacant. Mainly in this waiting time, IC devices to be tested are applied with a thermal stress of a high or low temperature.

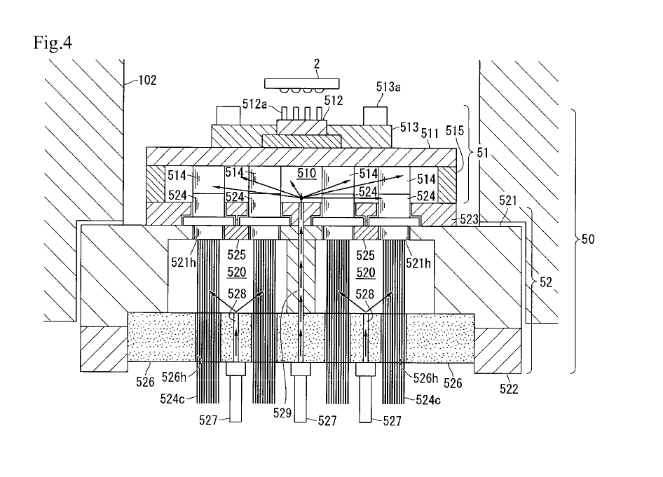

The test head 5 is placed under the test chamber 102 and, as shown in FIG. 3 and FIG. 4, the upper portion of the test section unit 50 provided on the test head 5 positions in the test chamber 102. The test trays TST are conveyed successively to above the test section unit 50, where IC devices 2 mounted on each test tray TST are brought to electrically contact with the sockets of the test section unit 50 and all IC devices 2 on the test tray TST are tested. On the other hand, the applied heat is removed from the test tray TST finished with the test in the unsoak chamber 103 to bring a temperature of the IC devices 2 back to the room temperature, then, the test tray TST is taken out to the unloader section 400 shown in FIG. 2.

As shown in FIG. 3, the test chamber 102 is provided with a casing 80 which composes a nearly airtight space on the upper side of the test section unit 50. Inside the casing 80 is provided with a temperature adjusting blower 90 and a temperature sensor 82.

The temperature adjusting blower 90 comprising a fan 92 and a heat exchanger 94 draws in an air inside the casing by the fan 92 and blows out through the heat exchanger 94 into inside the casing 80 to bring the inside of the casing 80 to have a predetermined temperature condition (a high or low temperature).

The heat exchanger 94 of the temperature adjusting blower 90 is composed of a radiating heat exchanger having a heat medium circulating therein or an electrothermal heater, etc. when bringing inside the casing to be at a high temperature and capable of providing a sufficient heat to keep inside the casing to be at the room temperature to a high temperature of, for example, 160° or so. While, when bringing inside the casing to be at a low temperature, the heat exchanger 94 is composed of an endothermic heat exchanger having a coolant, such as liquid nitride, circulating therein, etc., and capable of absorbing a sufficient heat to keep inside the casing to be at a low temperature of, for example, −60° to the room temperature. A temperature of inside the casing 80 is detected by a temperature sensor 82, and an air volume of the fan 92 and a heat amount of the heat exchanger 94, etc. are controlled to keep inside the casing 80 to be at a predetermined temperature.

The hot air or cool air (air) generated though the heat exchanger 94 of the temperature adjusting blower 90 circulates inside the casing by flowing at the upper portion of the casing 80 in the Y-axis direction, falling along a side wall of the casing on the opposite side of the temperature adjusting blower 90, going through a gap between a match plate 60 and the test head 5 and returning to the temperature adjusting blower 90.

As shown in FIG. 3, in the test chamber 102, pushers 30 for pressing IC devices 2 against the sockets 512 are provided above the upper side of the test section unit 50 provided with the sockets 512. The pushers 30 are held by adapters 62.

Each of the adapters 62 is held elastically by the match plate 60, and the match plate 60 is provided to be positioned above the test section unit 50 so that a test tray TST can be inserted between the pushers 30 and the sockets 512. The pushers 30 held by the match plate 60 are movable freely in the Z-axis direction with respect to the test head 5 or a drive plate 72 of a Z-axis drive 70.

Note that a test tray TST is conveyed from the vertical direction with respect to the paper surface (X axis) in FIG. 3 to between the pushers 30 and the sockets 512. As a conveying means of the test trays TST inside the chamber 100, a conveyor roller, etc. may be used. When conveying and moving the test tray TST, the drive plate 72 of the Z-axis drive 70 is elevated along the z-axis direction and a sufficient space for the test tray TST to be inserted is formed between the pushers 30 and the sockets 512.

As shown in FIG. 3, pressing portions 74 are fixed to the lower surface of the drive plate 72, and the pressing portions 74 press the upper surface of the adaptor 62 held by the match plate 60. A drive axis 78 is fixed to the drive plate 72, and a motor or other drive source (not shown) is connected to the drive axis 78. The drive source moves the drive axis 78 up and down in the Z-axis direction so that the pressing portions 74 can press the adaptors 62.

The test head 5 comprises a test head body accommodating a signal module for processing signals and a test section unit 50 attached detachably to the test head body. As shown in FIG. 4, the test section unit 50 comprises a socket board 51 and an interface member 52, wherein the interface member 52 is provided between the socket board 51 and the test head body and electrically connects the two.

The socket board 51 comprises a plate-shaped board body 511, a socket 512 provided to the upper side of the board body 511, a socket guide 513 provided to surround the socket 512, a frame-shaped frame 515 provided on the lower side of the board body 511, and a plurality of socket side connectors 514 provided inside (the internal space 510) of the frame 515 and electrically connected to the socket 512.

The socket 512 is provided with probe pins 512a connected to external terminals of an IC device 2. The socket guide 513 is provided with guide bushes 513a, to which guide pins formed on the pusher 30 are inserted. As a result that the guide pins of the pusher 30 are inserted to the guide bushes 513a, the pusher 30 and the socket guide 513 are aligned.

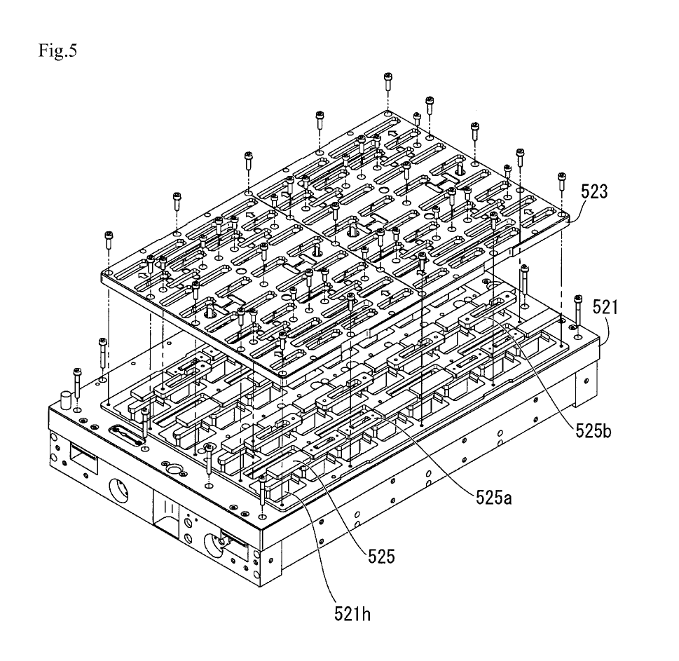

The interface member 52 comprises an upper frame 521, inside thereof is hollow, and a frame-shaped lower frame 522. Here, the hollow of the upper frame 521 is called an internal space 520 (of the interface member 52). The upper portion of the upper frame 521 is a substrate portion, where holes 521h are formed. A plurality of IF side connectors 524 are provided to pass through the holes 521h. A plate shaped heat insulator 525 is provided between a plurality of IF side connectors 524 passing through the same hole 521h (refer to FIG. 4 and FIG. 5). Due to the provision of the heat insulator 525, the hole 521h is in a nearly airtight state. Note that the IF side connectors 524 and the socket side connectors 514 are engaged, respectively.

As a material of the heat insulator 525, for example, a plastic resin, etc. having an excellent heat insulating property may be used. As the heat insulator to be used here, as shown in FIG. 5, other than the plate-shaped heat insulator 525 explained above, there are plate-shaped heat insulators 525a and 525b having a hole at the center portion. The heat insulator 525a is provided between a plurality of IF side connectors 524, and still another IF side connector 524 passes through the hole of the heat insulator 525a. Also, the heat insulator 525b is provided to the hole 521h of the upper frame 521, and an IF side connector 524 passes through the hole of the heat insulator 525b.

As shown in FIG. 4 and FIG. 5, connector covers 523 are attached to the substrate portion of the upper frame 521 so as to fix the IF side connectors 524.

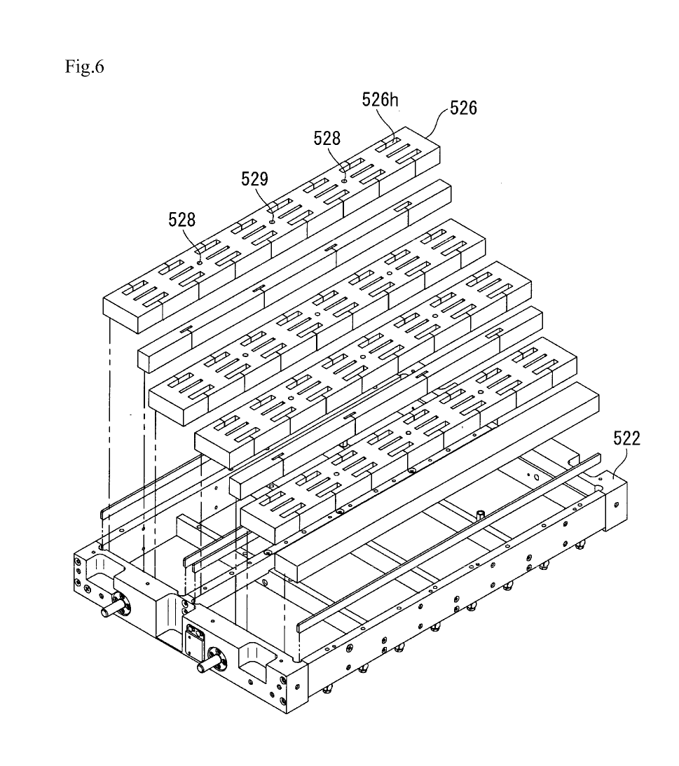

As shown in FIG. 4, cables 524c to be electrically connected to the test head body extend from the IF side connectors 524. On the other hand, as shown in FIG. 4 and FIG. 6, inside (opening portion) of the frame-shaped lower frame 522 is filled with a plurality of block-shaped heat insulators 526 in the plane direction. Holes 526h are formed on the heat insulators 526, and the cables 524c pass through the holes 526h. Due to the provision of heat insulators 526 as such, the opening portion of the lower frame 522 is in a nearly airtight state. Also, the cables 524c are clamped by the heat insulators 526 and their positions are regulated.

The hole 526h on the heat insulator 526 in the present embodiment has an exact size for the plurality of cables 524c extending from one IF side connector 524 to pass through, however, it is not limited to this and may have a size of allowing one cable 524c to pass through.

The heat insulator 526 is preferably made of an elastic material. Thereby, the heat insulators 526 can tightly fit in the inner side of the lower frame 522, and the airtightness can be improved to enhance the heat insulating property. Furthermore, the elastic material is preferably a porous elastic material having a number of closed cells. Such elastic materials have an excellent heat insulating property, in particular. As a heat insulator 526 material as such, for example, a porous silicone sponge having a number of closed cells, etc. are preferably used.

The heat insulators 526 are a plurality of blocks in the present embodiment and, thereby, the manufacturing process of letting the cables 524c pass through the holes 526h of each of the heat insulators 526 and fitting the heat insulators 526 in the lower frame 522 becomes easy.

On the heat insulators 526, vent paths 528 are formed for introducing a dry air to the internal space 520 of the interface member 52 (upper frame 521), and pipes 527 are connected to the vent paths 528. Also, the heat insulators 526, upper frame 521 and connector covers 523 have vent paths 529 formed thereon for introducing a dry air to the internal space 510 of the socket board 51, and the vent paths 529 are also connected to pipes 527. The pipes 527 are connected to a not shown dry air supplier. Note that the dry air supplier has a dry air temperature adjusting function.

In the test section unit 50 having the above configuration, the internal space 510 of the socket board 51 surrounded by the board body 511 and frame 515 of the socket board 51 and the connector cover 523 of the interface member 52 has high airtightness and an excellent heat insulating property due to the provision of the heat insulators 525 between the IF side connectors 524. Consequently, a heat loss of the test chamber 102 from the socket board 51 to the interface member 52 side can be hindered.

Also, the internal space 520 of the interface member 52 gains high airtightness and an excellent heat insulating property as a result that the heat insulators 526 are provided inside the lower frame 522. Consequently, a heat loss of the test chamber 102 from the interface member 52 to outside of the apparatus or to the test head body side can be hindered.

In the present embodiment, particularly, because both of the internal space 510 of the socket board 51 and the internal space 520 of the interface member 52 respectively have high airtightness as explained above, the test section unit 50 as a whole has a highly excellent heat insulating property.

Furthermore, by supplying a temperature-adjusted dry air from the dry air supplier to the internal space 510 of the socket board 51 though the pipes 527 and the vent paths 529 and by supplying the temperature-adjusted dry air to the internal space 520 of the interface member 52 through the pipes 527 and the vent paths 528, dew condensation can be efficiently prevented at the time of a low temperature test. Particularly, since the internal space 510 of the socket board 51 and the internal space 520 of the interface member 52 respectively have high airtightness, the dry air hardly finds a vent to the outside of the apparatus or to the test head body side, and dew condensation can be effectively prevented. Furthermore, because the internal space 510 of the socket board 51 and the internal space 520 of the interface member 52 are nearly completely isolated and do not have large volumes, there is another advantage that convection hardly arises and a heat of the dry air hardly escapes to outside of the apparatus or to the test head body side.

Therefore, according to the test section unit 50 explained above, it is possible to control IC devices 2 to be a predetermined set temperature and to conduct a test at a precise temperature. Also, it is possible to prevent short-circuiting caused by dew condensation inside the test section unit 50.

The embodiment explained above is described to facilitate understanding of the present invention and is not to limit the present invention. Accordingly, respective elements disclosed in the above embodiment include all design modifications and equivalents belonging to the technical scope of the present invention.

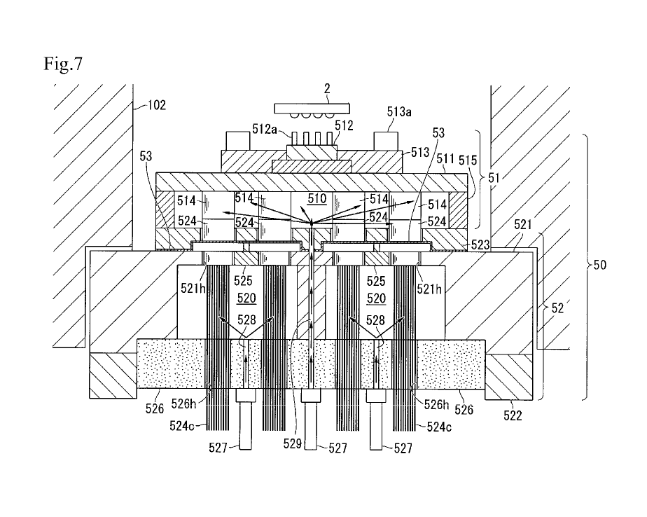

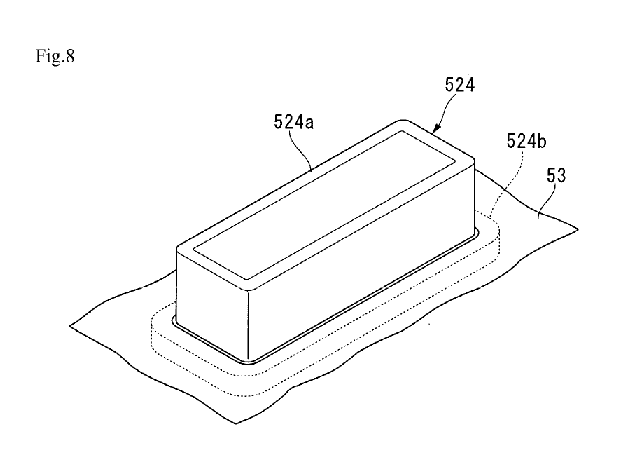

For example, as shown in FIG. 7 and FIG. 8, between the plurality of IF side connectors 524, a heat insulating sheet 53 covering in the plane direction of the substrate portion of the upper frame 521 may be provided. Here, each of the IF side connectors 524 is provided with an engaging portion 524a to engage with a socket side connector 514 and a flange 524b formed beneath the engaging portion 524a.

As shown in FIG. 8, the heat insulating sheet 53 have holes formed thereon, each having a size for allowing the engaging portion 524a of the IF side connector 524 to pass through but not allowing the flange 524b to pass through. The heat insulating sheet 53 is provided, so that the engaging portions 52a of the IF side connector 524 pass through the holes thereof and the flanges 524b contact closely thereto. In the present embodiment, the heat insulating sheet 53 is pressed against the substrate portion of the upper frame 521 by the connector covers 523 so as to be closely contact with the flanges 524b of the IF side connectors 524 and the substrate portion of the upper frame 521.

As the heat insulating sheet 53, for example, a sheet formed by stacking a metal layer made of aluminum, etc. on a porous sheet, etc. may be used.

As a result of providing the heat insulating sheet 53 as explained above, a heat insulating property of the internal space 510 of the socket board 51 and the internal space 520 of the interface member 52 can be furthermore enhanced.

### INDUSTRIAL APPLICABILITY

The present invention is useful for an electronic device testing apparatus for conducting a test by controlling electronic devices to be a predetermined temperature.

1. An interface member, being provided between a body part of a test head to be used in an electronic device testing apparatus and a socket board having a socket to be mounted with an electronic device to be tested and a plurality of connectors electrically connected to the socket, for electrically connecting the body part of the test head with the socket board, comprising:
connectors to be engaged with socket side connectors provided to the socket board; and
a frame for supporting the connectors;
wherein
the frame has a hole formed thereon for allowing a plurality of the connectors to pass through; and
a heat insulator is provided between the plurality of connectors passing through the same hole.

2. An interface member, being provided between a body part of a test head to be used in an electronic device testing apparatus and a socket board having a socket to be mounted with an electronic device to be tested and a plurality of connectors electrically connected to the socket, for electrically connecting the body part of the test head with the socket board, comprising:
connectors to be engaged with socket side connectors provided to the socket board; and
a frame for supporting the connectors;
wherein
a heat insulator is provided between a cable extending from one of the connectors and a cable extending from another one of the connectors.

3. The interface member as set forth in claim 2, wherein the heat insulator has a hole formed thereon, and the cable passes through a hole of the heat insulator.

4. The interface member as set forth in claim 2, wherein the heat insulator fills the frame in the plane direction.

5. The interface member as set forth in claim 4, wherein the heat insulator has a block shape, and a plurality of the block-shaped heat insulators are provided contiguously to fill the frame in the plane direction.

6. The interface member as set forth in claim 2, wherein the heat insulator is made of an elastic material.

7. The interface member as set forth in claim 6, wherein the elastic material is a porous elastic material having a number of closed cells.

8. The interface member as set forth in claim 2, wherein:
the frame has a hole formed thereon for allowing a plurality of the connectors to pass through; and
a second heat insulator is provided between the plurality of connectors passing through the hole.

9. The interface member as set forth in claim 2, wherein inside of the frame form a nearly airtight space.

10. The interface member as set forth in claim 9, wherein a dry air is introduced to an internal space of the frame.

11. The interface member as set forth in claim 10, wherein the heat insulator has a vent path formed thereon for introducing the dry air.

12. An interface member, being provided between a body part of a test head to be used in an electronic device testing apparatus and a socket board having a socket to be mounted with an electronic device to be tested and a plurality of connectors electrically connected to the socket, for electrically connecting the body part of the test head with the socket board, comprising:
connectors to be engaged with socket side connectors provided to the socket board; and
a frame for supporting the connectors;
wherein a heat insulating sheet spread in the plane direction of the frame is provided between a plurality of the connectors.

13. The interface member as set forth in claim 12, wherein:
the connector has a flange formed beneath an engaging portion;
the heat insulating sheet has a hole formed thereon having a size for allowing the engaging portion of the connector to pass through but not allowing the flange to pass through; and
the heat insulating sheet let the engaging portion of the connector pass through the hole and contact closely with the flange.

14. A test section unit to be attached to a body part of a test head, comprising:
a socket board having a socket to be mounted with an electronic device to be tested and a plurality of connectors electrically connected to the socket; and
the interface member as set forth in claim 1;
wherein a space surrounded by the socket board and the interface member is nearly airtight.

15. A test section unit to be attached to a body part of a test head, comprising:
a socket board having a socket to be mounted with an electronic device to be tested and a plurality of connectors electrically connected to the socket; and
the interface member as set forth in claim 2.

16. A test section unit to be attached to a body part of a test head, comprising:
a socket board having a socket to be mounted with an electronic device to be tested and a plurality of connectors electrically connected to the socket; and
the interface member as set forth in claim 8;
wherein a space surrounded by the socket board and the interface member is nearly airtight.

17. A test section unit to be attached to a body part of a test head, comprising:
a socket board having a socket to be mounted with an electronic device to be tested and a plurality of connectors electrically connected to the socket; and
the interface member as set forth in claim 12;
wherein a space surrounded by the socket board and the interface member is nearly airtight.

18. The test section unit as set forth in claim 14, wherein a dry air is introduced to the nearly airtight space.

19. The test section unit as set forth in claim 18, wherein the interface member has a vent hole formed thereon for introducing the dry air.

20. A test head, comprising:
a test head body; and
the test section unit as set forth in claim 14 to be attached to the test head body.

21. A test head, comprising:
a test head body;
the test section unit as set forth in claim 14 to be attached to the test head body; and
a device for supplying a dry air to the nearly airtight space in the test section unit.

22. A test head, comprising:
a test head body;
a test section unit to be attached to the test head body and provided with the interface member as set forth in claim 10; and
a device for supplying a dry air to inside the frame in the interface member.

23. An electronic device testing apparatus, comprising:
the test head as set forth in claim 20; and
an electronic device handling apparatus for handling an electronic device to be tested and mounting the electronic device on be tested to a socket of the test head.

24. An electronic device testing apparatus, comprising:
the test head as set forth in claim 21; and
an electronic device handling apparatus for handling an electronic device to be tested and mounting the electronic device to be tested on a socket of the test head.

25. An electronic device testing apparatus, comprising:
the test head as set forth in claim 22; and
an electronic device handling apparatus for handling an electronic device to be tested and mounting the electronic device to be tested on a socket of the test head.

26. The electronic device as set forth in claim 23, wherein the electronic device handling apparatus is provided with a chamber for heating and/or cooling an electronic device to be tested to be a predetermined temperature.
